(19) United States
(12) Patent Application Publication
(10) Pub. No.: US 2015/0346603 A1
(43) Pub. Date: Dec. 3, 2015

(54) METHOD OF REMOVING PHOTORESIST, EXPOSURE APPARATUS AND METHOD OF MANUFACTURING DISPLAY SUBSTRATE

(71) Applicants: BOE TECHNOLOGY GROUP CO., LTD., Beijing (CN); BEIJING BOE DISPLAY TECHNOLOGY CO., LTD., Beijing (CN)

(72) Inventors: Zhichao ZHANG, Beijing (CN); Zongjie GUO, Beijing (CN); Zheng LIU, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 14/421,570

(22) PCT Filed: Jun. 26, 2014
(86) PCT No.: PCT/CN2014/080894

§ 371 Date: Feb. 13, 2015

(30) Foreign Application Priority Data
Sep. 26, 2013 (CN) 201310446586.X

(51) Int. Cl. G03F 7/42; G03F 7/32; G03F 7/20; H01L 27/12; H01L 21/308

(52) U.S. Cl. CPC G03F 7/42; H01L 27/1288; H01L 21/3083; G03F 7/70058; G03F 7/20; G03F 7/32; G03F 7/2004

(57) ABSTRACT

A method of removing a photoresist, an exposure apparatus and a method of manufacturing a display substrate are disclosed. The method of removing a photoresist includes the following steps: exposing the photoresist (43) remaining on the substrate (41) after the substrate is subjected to a patterning process; and removing the exposed photoresist (45) by a developing process. In this way, the necessities for the stripping apparatus used in stripping process, the high power apparatus and the chemical gas both used in the ashing process can be eliminated, thereby reducing the equipment cost and production cost.

### TECHNICAL FIELD

The present disclosure relates to a method of removing a photoresist, an exposure apparatus, and a method of manufacturing a display substrate.

### BACKGROUND

The lithography process, which is usually used in manufacturing an array substrate, comprises: coating a layer of photoresist on a substrate; forming a desired pattern by exposing and developing the photoresist; etching the substrate with the photoresist pattern mask; forming the array substrate by stripping off the remaining photoresist with a stripping apparatus. The principle of stripping off the photoresist from the substrate is to dissolve the photoresist with a stripping solution provided by a stripping apparatus for the purpose of stripping off the photoresist. Thus, in practical production, it is necessary to provide an individual stripping apparatus for stripping the photoresist.

In the process of manufacturing the TFT array substrate, the channel is formed by ashing process. The ashing process comprises: coating a layer of photoresist on the substrate; removing predetermined thickness of the photoresist in the position corresponding to the channel pattern by partial exposing and developing the photoresist; forming a required channel pattern by removing the photoresist remaining in the position corresponding to the channel pattern with the chemical gas ejected from a high power apparatus; and forming the channel of the TFT array substrate by stripping off the photoresist out of the position corresponding to the channel pattern with the stripping apparatus. Thus, in ashing process, it is necessary to provide a high power apparatus, which ejects the chemical gas to react with the photoresist for removing the desired thickness of the photoresist.

### SUMMARY

An embodiment of the present invention provides a method of removing a photoresist remaining on a substrate after the substrate is subjected to a patterning process, which comprises: exposing the photoresist remaining on the substrate after the substrate is subjected to the patterning process; and removing the exposed photoresist by a developing process.

As an example, exposure energy for exposing the photoresist is determined by a thicknesses of the photoresist that needs to be removed; and the photoresist remaining on the substrate after the substrate is subjected to the patterning process is exposed with the determined exposure energy.

As an example, the removing of the photoresist remaining on the substrate after the substrate is subjected to the patterning process is to entirely strip off the photoresist remaining on the substrate after the substrate is subjected to the patterning process, and the thicknesses of the photoresist that needs to be removed is a maximum thickness of the photoresist remaining on the substrate after the substrate is subjected to the patterning process.

As an example, the removing of the photoresist remaining on the substrate after the substrate is subjected to the patterning process is to ash the photoresist remaining on the substrate after the substrate is subjected to the patterning process, and the thicknesses of the photoresist that needs to be removed is a partial thickness of the photoresist remaining on the substrate after the substrate is subjected to the patterning process.

According to process requirements, the exposure energy for exposing the photoresist is determined in such a way that the thickness of the removed photoresist is same to the predetermined thickness of the photoresist to be removed. Thus, the method is adjustable and can meet the requirements of different processes.

As an example, the exposure intensity for exposing the photoresist is determined by a thicknesses of the photoresist that needs to be removed, and the photoresist remaining on the substrate subjected to the patterning process is exposed with the determined exposure intensity; alternatively, the exposure duration for exposing the photoresist is determined by the thicknesses of the photoresist that needs to be removed, and the photoresist remaining on the substrate subjected to the patterning process is exposed with the determined exposure duration.

As an example, the step of exposing the photoresist remaining on the substrate after the substrate is subjected to the patterning process comprises: exposing the photoresist remaining on the substrate after the substrate is subjected to the patterning process by using an exposure light source.

As an example, the exposure light source is a strip-like light source, wherein the strip-like light source moves in a uniform velocity along a direction parallel to the substrate and simultaneously irradiates the substrate, so that exposure degree of the photoresist on the substrate is uniform.

As an example, the exposure light source is a surface light source, wherein the surface light source irradiates the substrate in a vertical direction, so that exposure degree of the photoresist on the substrate is uniform.

An embodiment of the present invention further provides a method of manufacturing a display substrate, which comprises steps of: forming a device pattern on a substrate by a patterning process using a photoresist, and removing the photoresist remaining on a substrate after the substrate is subjected to the patterning process, wherein the step of removing the photoresist remaining on the substrate after the substrate is subjected to the patterning process comprises the above photoresist removing method.

As an example, the step of forming a device pattern on a substrate by a patterning process using a photoresist comprises: forming a material film of the device on the substrate; forming a photoresist film on the material film of the device; performing an exposing process with a mask and an developing processes on the photoresist film to remove a portion of the photoresist film and expose a portion of the material film of the device, other portions of the photoresist film are left on the substrate; and etching the exposed portion of the material film to form the device pattern.

As an example, the display substrate is a thin film transistor array substrate.

As an example, the thin film transistor array substrate comprises a thin film transistor (TFT), a pixel electrode, a gate line and a data line.

As an example, the device pattern comprises a gate, an active layer, source and drain electrodes, the pixel electrode, the gate line, or the data line.

An embodiment of the present invention further provides an exposure apparatus, which comprises an exposure light source, the exposure light source comprises a mask exposure light source and a photoresist removing exposure light source, wherein the mask exposure light source is configured for irradiating a film layer on a substrate while the film layer are exposed with a mask; the photoresist removing exposure light source is configured for irradiating the photoresist on the substrate after the substrate is subjected to the patterning process during the above method of removing the photoresist remaining on a substrate after the substrate is subjected to a patterning process.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1a schematically illustrates a substrate subjected to the patterning process in an embodiment of the present invention.

FIG. 1b schematically illustrates a substrate subjected to the patterning process on which a photoresist is entirely exposed in an embodiment of the present invention.

FIG. 1c schematically illustrates a substrate subjected to the patterning process on which the photoresist is stripped off in an embodiment of the present invention.

FIG. 2a schematically illustrates a substrate on which the photoresist is coated in an embodiment of the present invention.

FIG. 2b schematically illustrates a substrate on which the photoresist film is subjected to exposure in an embodiment of the present invention.

FIG. 2c schematically illustrates a substrate on which a desired pattern of the photoresist film is formed in an embodiment of the present invention.

FIG. 2d schematically illustrates a substrate on which a desired pattern of the metal film is formed by etching process in an embodiment of the present invention.

FIG. 2e schematically illustrates a substrate on which an unexposed photoresist film is exposed in an embodiment of the present invention.

FIG. 2f schematically illustrates a substrate on which the photoresist is removed with a developer in an embodiment of the present invention.

FIG. 3a schematically illustrates a substrate on which a first channel pattern is formed thereon after the substrate is subjected to a patterning process in an embodiment of the present invention.

FIG. 3b schematically illustrates a substrate on which the photoresist is subjected to a first exposure process in an embodiment of the present invention.

FIG. 3c schematically illustrates a substrate on which a second channel pattern is formed thereon in an embodiment of the present invention.

FIG. 3d schematically illustrates a substrate on which the channel pattern is formed by etching the substrate according to the second channel pattern in an embodiment of the present invention.

FIG. 4a schematically illustrates a substrate on which a photoresist is coated during the process of manufacturing a substrate containing the channel in an embodiment of the present invention.

FIG. 4b schematically illustrates a substrate on which a first channel pattern is formed thereon during the process of manufacturing a substrate containing the channel in an embodiment of the present invention.

FIG. 4c schematically illustrates a substrate with the first channel pattern on which the photoresist is subjected to the second exposure process during the process of manufacturing a substrate containing the channel in an embodiment of the present invention.

FIG. 4d schematically illustrates a substrate on which the second channel pattern is formed during the process of manufacturing a substrate containing the channel in an embodiment of the present invention.

FIG. 4e schematically illustrates a substrate on which the desired pattern is formed by etching the substrate during the process of manufacturing a substrate containing the channel in an embodiment of the present invention.

FIG. 4f schematically illustrates a substrate on which unexposed photoresist film is subjected to exposure during the process of manufacturing a substrate containing the channel in an embodiment of the present invention.

FIG. 4g schematically illustrates a substrate on which the photoresist is removed during the process of manufacturing a substrate containing the channel in an embodiment of the present invention.

FIG. 5 schematically illustrates an exposure process performed on the photoresist with a strip-like light source which emits short wavelength light in an embodiment of the present invention.

FIG. 6 schematically illustrates an exposure process performed on the photoresist with a surface light source which emits short wavelength light in an embodiment of the present invention.

### DETAILED DESCRIPTION

In order to make objects, technical details and advantages of the embodiments of the invention apparent, hereinafter, the technical solutions of the embodiments of the invention will be described in a clearly and fully understandable way in connection with the drawings related to the embodiments of the invention. It is obvious that the described embodiments are just a part but not all of the embodiments of the invention. Based on the described embodiments of the invention, those ordinarily skilled in the art can obtain other embodiment(s), without any inventive work, which should be within the scope sought for protection by the invention.

In embodiments of the present invention, after the substrate is subjected to the patterning process, the photoresist left on the substrate is removed by exposing the photoresist and developing the exposed photoresist. In this way, the necessities for the stripping apparatus used in stripping process, the high power apparatus and the chemical gas both used in the ashing process can be eliminated, thereby reducing the equipment cost and production cost.

An embodiment of the present invention provides a method of removing a photoresist remaining on a substrate after the substrate is subjected to the patterning process, and the method comprises:

Step 101: exposing the photoresist remaining on the substrate after the substrate is subjected to the patterning process;

Step 102: removing the exposed photoresist by a developing process, namely, removing the exposed photoresist by using a developing agent such as a developer.

In the embodiment of the present invention, “the photoresist remaining on the substrate after the substrate is subjected to the patterning process” refers to the photoresist with a pattern which is formed by using the patterning process which includes exposure, developing, and etching. For example, the procedure of forming a gate pattern on a substrate comprises: coating a gate material film on the substrate; forming a photoresist film by coating a layer of photoresist on the gate material film; exposing and developing the photoresist film according to the predetermined gate pattern, so as to form a photoresist pattern having a same pattern with the gate pattern; and then forming the gate pattern by etching the exposed gate material. After the step of exposing and developing the photoresist film according to the gate pattern, there is unexposed photoresist remaining on the substrate, the unexposed photoresist is “the photoresist remaining on the substrate after the substrate is subjected to the patterning process”.

The patterning process usually includes one or more of the following steps: forming a material film; coating a photoresist on the material film; exposing and developing the photoresist according to a desired pattern, so as to form a photoresist pattern; and etching the material film according to the photoresist pattern.

It is noted that the above exemplified patterning process is preference. The patterning process is not limited to these embodiments. In other embodiments, any patterning processes that can form patterns could be also adopted. For example, 3D print technology, which could be used to form the pattern, should be within the scope of the invention.

In the embodiment of the present invention, the developing process for the positive photoresist refers to the following situation: after being exposed, the exposed photoresist is removed by dissolving in a developer, and the unexposed photoresist is left on the substrate. Whereas for the negative photoresist, after being exposed, the unexposed photoresist is removed by the developer, and the exposed photoresist is left on the substrate.

As an example, the step 101 comprises: determining exposure energy for exposing the photoresist by the thickness of photoresist that needs to be removed; and exposing the photoresist remaining on the substrate after the substrate is subjected to the patterning process with the determined exposure energy. The exposure energy is affected by the factors including, but not limited to, the exposure intensity and the exposure duration. That is, the exposure intensity for exposing the photoresist can be determined by the thickness of the photoresist that needs to be removed, and then the photoresist remaining on the substrate after the substrate is subjected to the patterning process is exposed with the determined exposure intensity; alternatively, the exposure duration for exposing the photoresist can be determined by the thicknesses of the photoresist that needs to be removed, and then the photoresist remaining on the substrate after the substrate is subjected to the patterning process is exposed with the determined exposure duration.

Both the exposure duration and the exposure intensity are in proportion to the thickness of the photoresist that needs to be exposed. For the photoresists with same compositions as each other, the thickness of the exposed photoresist increases with either the increase of the exposure intensity or the increase of the exposure duration. For the photoresists with the different compositions, even if the photoresists are exposed with same exposure duration or same exposure intensity, the exposed thickness of the photoresists may be different from each other due to the different sensitivity of the photoresists. Thus, the exposure duration or the exposure intensity should be determined by both the photoresist composition and the thickness of the photoresist that needs to be exposed.

Depending on the thickness of the photoresist that needs to be removed, there are two situations in exposure process: one is to strip off the photoresist remaining on the substrate after the substrate is subjected to the patterning process; another one is to ash the photoresist remaining on the substrate after the substrate is subjected to the patterning process. The two situations are described in the following:

Situation I: The Photoresist Remaining on the Substrate Subjected to the Patterning Process Needs to be Stripped Off.

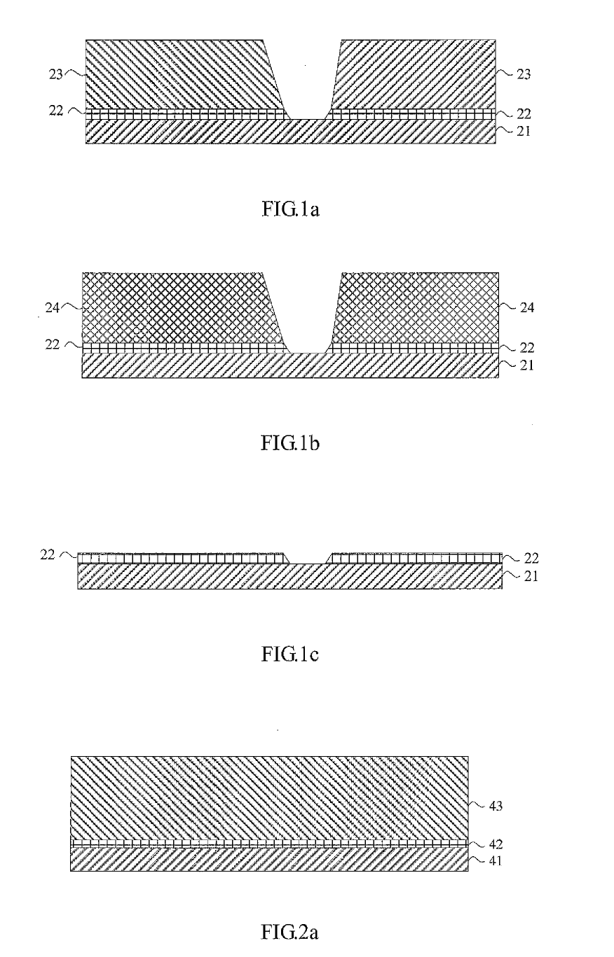

FIG. 1a schematically illustrates the substrate after being subjected to the patterning process, where reference numeral 21 represents a substrate, reference numeral 22 represents a metal film, and reference numeral 23 represents a photoresist that needs to be removed. The photoresist 23 on the substrate is exposed by using an exposure light source. As illustrated in FIG. 1b, after the photoresist 23 on the substrate is exposed with the exposure light source, the photoresist is entirely exposed. Reference numeral 24 represents the resulting photoresist that need to be removed after the exposure. The substrate subjected to the exposure process is developed by immersing the substrate in a developer, so as to remove the photoresist 24 on the substrate. The substrate after the photoresist is removed is illustrated in FIG. 1c. By using the method, the photoresist can be stripped off without the individual stripping apparatus.

As an example, while the entire photoresist remaining on the substrate after the substrate is subjected to the patterning process needs to be stripped off and the thickness of the photoresist is different at different locations of the substrate, the thicknesses of the photoresist that needs to be removed is the maximum thickness of the photoresist on the substrate. At this time, the exposure duration and the exposure intensity can be determined by the maximum thickness of the photoresist on the substrate, and also can be adjusted depending on the various thickness of the photoresist at the different locations of the substrate.

An embodiment of the present invention provides a method of manufacturing a substrate, comprising:

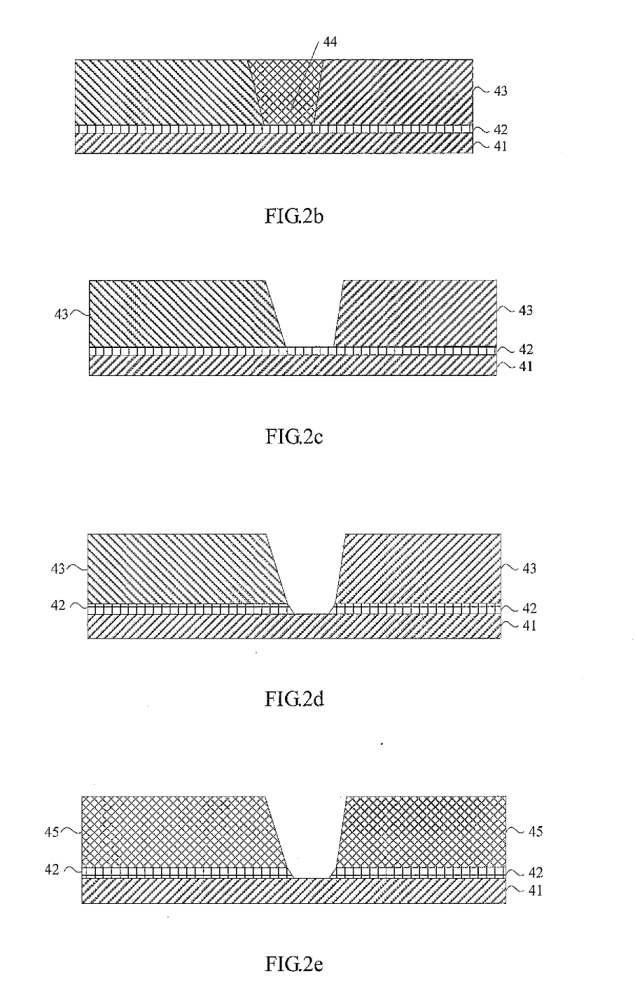

Step 301: forming a photoresist film by coating a layer of photoresist on a substrate; the substrate on which photoresist is coated is illustrated in FIG. 2a, where reference numeral 41 represents the substrate, reference numeral 42 represents a metal film, and reference numeral 43 represents the photoresist;

Step 302: exposing the photoresist film with a mask according to the predetermined pattern; the substrate after the exposure is illustrated in FIG. 2b, where reference numeral 43 represents the unexposed photoresist, reference numeral 44 represents the exposed photoresist according to the predetermined pattern;

Step 303: removing the exposed photoresist 44 by a developing process, and forming a desire photoresist pattern; the substrate on which the desired photoresist pattern is formed is illustrated in FIG. 2d;

step 304: forming a desired pattern of the metal film on the substrate by etching the metal film 42 according to the photoresist pattern; the substrate on which the desired pattern of metal film is formed is illustrated in FIG. 2d;

The following steps are the above-mentioned steps included in the method of removing the photoresist:

Step 305: exposing the unexposed photoresist with an exposure light source, such that the thickness of the exposed photoresist is same as the maximum thickness of the photoresist on the substrate; the substrate subjected to the exposure of the unexposed photoresist film is illustrated in FIG. 2e, where reference numeral 45 represents the exposed photoresist;

Step 306: removing the photoresist 45 on the substrate with the developer, for example, by immersing the substrate subjected to the exposure in a developer or ejecting the developer to the substrate; the substrate on which the photoresist is removed is illustrated in FIG. 2f.

Situation II: The Photoresist Remaining on the Substrate Subjected to the Patterning Process Needs to be Ashed.

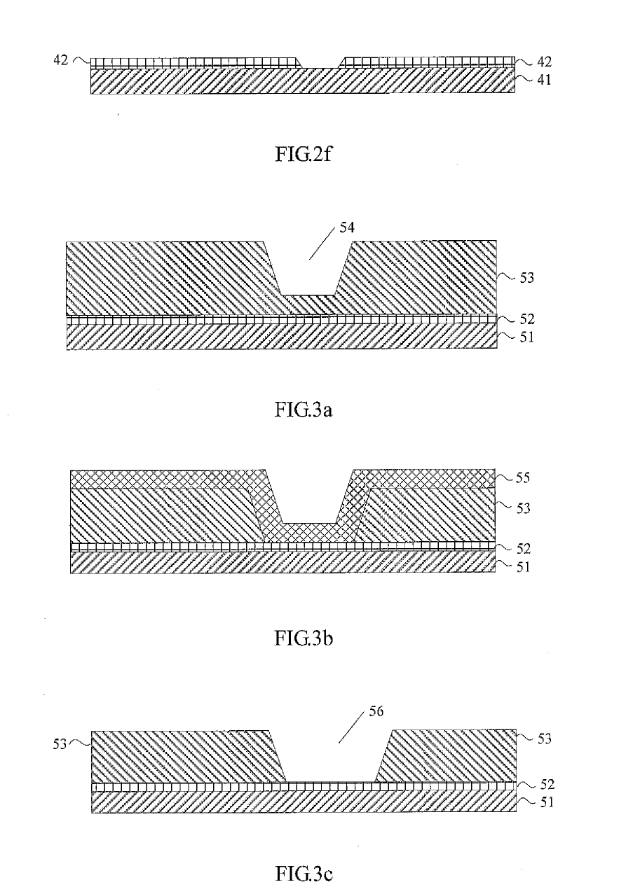

The embodiment of the present invention takes an example of ashing the photoresist on the substrate with a channel pattern to be formed thereon. The substrate on which a first channel pattern of the photoresist is formed after patterning process is illustrated in FIG. 3a, where reference numeral 51 represents the substrate, reference numeral 52 represents the metal film, reference numeral 53 represents the photoresist, reference numeral 54 represents the first channel pattern; at this time, a given thickness of the photoresist is remained in the first channel pattern.

A known method of removing the photoresist remaining in the first channel pattern comprises: ejecting a chemical gas on the photoresist by a high power apparatus to entirely etching off the photoresist at the first channel pattern and partially etching the photoresist in other regions of the substrate without the first channel pattern formed thereon, where the thickness of the removed photoresist in other regions is equal to the thickness of the removed photoresist remaining in the first channel pattern.

However, in an embodiment of the present invention, the method of removing the photoresist remaining in the first channel pattern 54 comprises:

performing a first exposure process on the photoresist with the exposure light source, wherein the thickness of the exposed photoresist equals to the thickness of the photoresist remaining in the first channel pattern; In FIG. 3b, reference numeral 55 represents the resulting photoresist after the first exposure process; and

developing the substrate which is subjected to the first exposure process, so as to remove the exposed photoresist and form a second channel pattern 56 in the remaining photoresist; the substrate on which the second channel pattern is formed is illustrated in FIG. 3c; forming a channel pattern by etching the metal film 52 according to the second channel pattern 56; the substrate on which the channel pattern is formed is illustrated in FIG. 3d.

Accordingly, an embodiment of the present invention provides a method of manufacturing a thin film transistor array substrate having a channel region, the method comprises:

Step 601: forming a photoresist film by coating a layer of the photoresist on a substrate; the substrate coated with the photoresist film is illustrated in FIG. 2a, where reference numeral 71 represents the substrate, reference numeral 72 represents a metal film, and reference numeral 73 represents the photoresist;

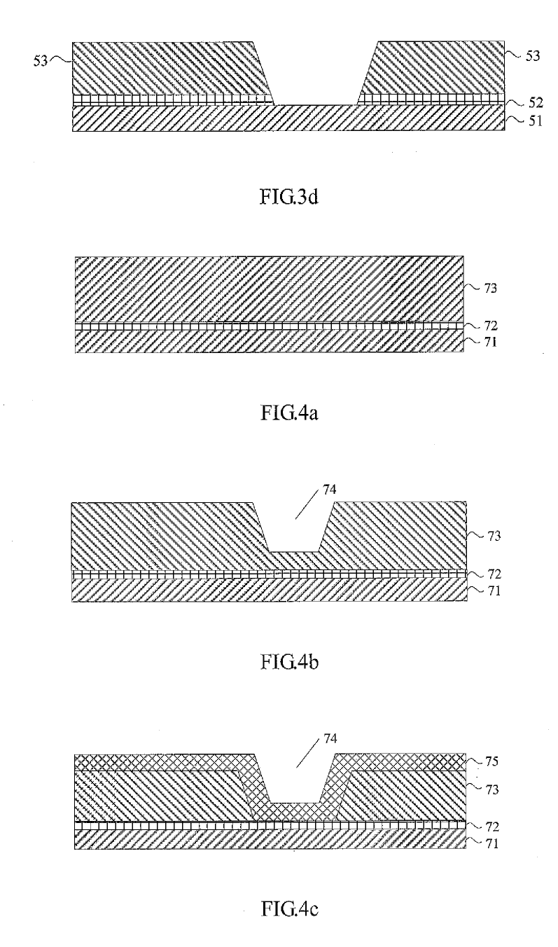

Step 602: performing a first exposure process and a developing process on the photoresist film according to a predetermined channel pattern to form a first channel pattern 74 in the photoresist film; the substrate with the first channel pattern 74 formed thereon is illustrated in FIG. 4b;

Step 603: as illustrated in FIG. 4c, performing a second exposure process on the photoresist with the first channel pattern 74 formed therein, wherein the thickness of the exposed photoresist is equal to the thickness of the photoresist remaining in the first channel pattern 74; reference numeral 75 represents the exposed photoresist, reference numeral 73 represents the unexposed photoresist;

Step 604: removing the exposed photoresist 75 to form a second channel pattern 76 in photoresist film; the substrate with the second channel pattern formed thereon is illustrated in FIG. 4d;

Step 605: etching the metal film 72 according to the second channel pattern 76 formed in the photoresist film to form a desired pattern of metal film; the substrate on which the desired pattern of metal film is formed is illustrated in FIG. 4e;

Step 606: exposing the unexposed photoresist 73 with an exposure light source wherein the thickness of the exposed photoresist equals to the thickness of the photoresist 73 remaining on the substrate; the substrate on which the unexposed photoresist is exposed is illustrated in FIG. 4f;

Step 607: immersing the substrate subjected to the exposure process in a developer to remove the remaining photoresist on the substrate; the substrate on which the photoresist is removed is illustrated in FIG. 4g.

In the embodiments of the present invention, the exposure light source refers to the light source with which the photoresist can be exposed, such as short wavelength light source. The exposure light source is not limited to these embodiments and also may include any other types of the exposure light source that can expose the photoresist. These exposure light sources should be within the scope of the invention.

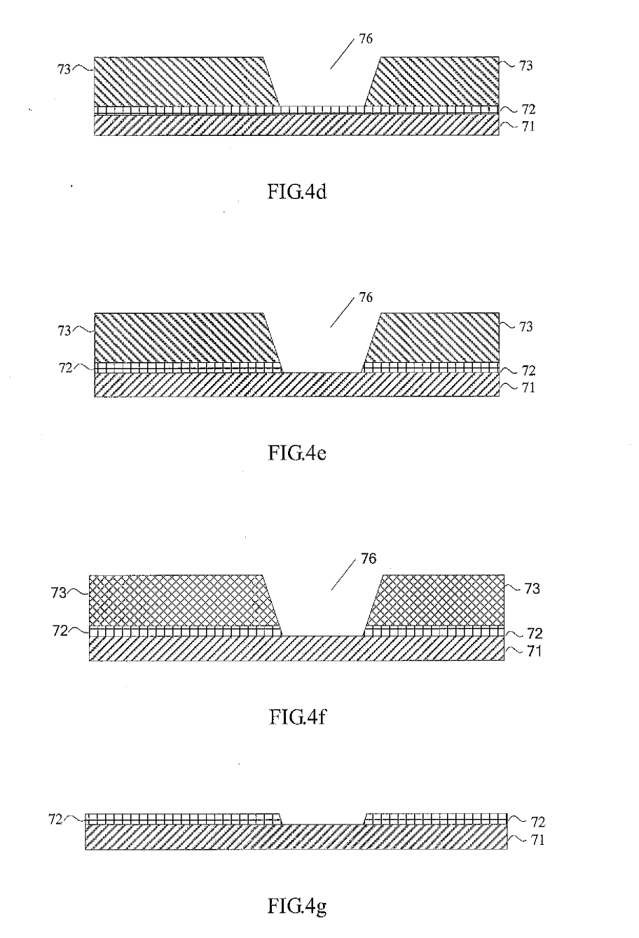

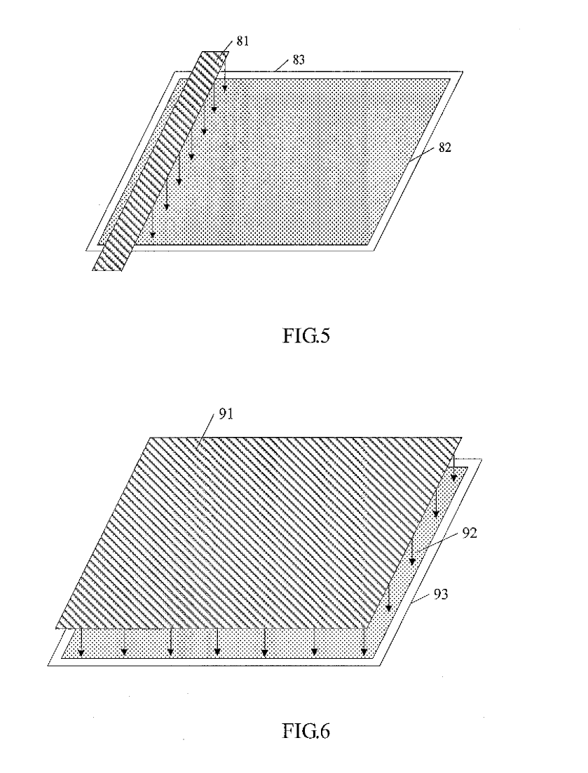

The exposure light source in the embodiments of the present invention includes, but not limited to, a white light source and an ultraviolet light source. The light source emitting the light of short wavelength can be a strip-like light source, a surface light source, or a light source with arbitrary shape that can irradiate the photoresist on the substrate with uniform light intensity. As illustrated in FIG. 5, the exposure light source is a strip-like light source, when the light irradiates the substrate, the strip-like light source moves in a uniform velocity and in a direction parallel to the substrate, so that the exposure degrees of the photoresist on the substrate are uniform; where reference numeral 81 represents the exposure light source, reference numeral 82 represents photoresist, reference numeral 83 represents the substrate. When the exposure light source is a surface light source and the area of the light source is equal to the area of the substrate, the light source is arranged parallel to the substrate and the light emitted from the light source irradiates the substrate in a vertical direction, so that the exposure degrees of the photoresist on the substrate are uniform; when the exposure light source is a surface light source and the area of the light source is smaller than the area of the substrate, the light emitted from the light source irradiates the different portions of the substrate respectively, so that the exposure degrees of the photoresist on the substrate are uniform. FIG. 6 schematically illustrates the photoresist on the substrate is irradiated with a surface light source, where reference numeral 91 represents the exposure light source, reference numeral 92 represents the photoresist, reference numeral 93 represents the substrate.

In the embodiment of the present invention, 4-mask patterning process is taken as an example, but the present invention is not limited to the above 4-mask patterning process. The patterning process may used for any times, as long as the photoresist needs to be removed after the patterning process, it could be used in the embodiments of the present invention.

An embodiment of the present invention further provides a method of manufacturing a display substrate, the method comprises steps of: forming a device pattern on the substrate by a patterning process using a photoresist; and removing the photoresist remaining on the substrate after the substrate is subjected to the patterning process, where the step of removing the photoresist remaining on the substrate after the substrate is subjected to the patterning process comprises any one of above photoresist removing methods. For example, the method of manufacturing the display substrate comprises: exposing the photoresist remaining on the substrate which is subjected to the patterning process; and removing the exposed photoresist by a developing process.

For example, the display substrate is a thin film transistor array substrate; the thin film transistor array substrate comprises a thin film transistor, a pixel electrode, a gate line and a data line.

For example, the device pattern comprises patterns of gate, active layer, source and drain electrodes, the pixel electrode, the gate line, or the data line.

For example, the step of exposing the photoresist remaining on the substrate which is subjected to the patterning process comprises: determining exposure energy for exposing the photoresist by the thickness of photoresist that needs to be removed; and exposing the photoresist remaining on the substrate after the substrate is subjected to the patterning process with the determined exposure energy. The exposure energy is affected by the factors including, but not limited to, the exposure intensity and the exposure duration. That is, the exposure intensity for exposing the photoresist can be determined by the thickness of the photoresist that needs to be removed, and then the photoresist remaining on the substrate after the substrate is subjected to the patterning process is exposed with the determined exposure intensity; alternatively, the exposure duration for exposing the photoresist can be determined by the thicknesses of the photoresist that needs to be removed, and then the photoresist remaining on the substrate after the substrate is subjected to the patterning process is exposed with the determined exposure duration.

Both the exposure duration and the exposure intensity are in proportion to the thickness of the photoresist that needs to be exposed. For the photoresists with same compositions as each other, the thickness of the exposed photoresist increases with either the increase of the exposure intensity or the increase of the exposure duration. For the photoresists with the different compositions, even if the photoresists are exposed with same exposure duration or same exposure intensity, the exposed thickness of the photoresists may be different from each other due to the different sensitivity of the photoresists. Thus, the exposure duration or the exposure intensity should be determined by both the photoresist composition and the thickness of the photoresist that needs to be exposed.

Depending on the thickness of the photoresist that needs to be removed, there are two situations in exposure process: one is to strip off the photoresist remaining on the substrate after the substrate is subjected to the patterning process; another one is to ash the photoresist remaining on the substrate after the substrate is subjected to the patterning process. The two cases have been described above in details and will not be iterated.

As an example, the step of forming a device pattern on the substrate by patterning process using a photoresist comprises:

Step 1001: forming a material film of a desire device on the substrate;

Step 1002: forming a photoresist film on the material film of the device;

Step 1003: performing exposure and developing processes with a mask on the photoresist film to remove a portion of the photoresist film and expose a portion of the material film of the device, other portions of the photoresist film is left on the substrate; and

Step 1004: etching the exposed portion of the material film to form the device pattern.

An embodiment of the present invention further provides an exposure apparatus used in above methods and configured for removing the photoresist, the exposure apparatus comprises a exposure light source, which further comprises a mask exposure light source and a photoresist removing exposure light source. The mask exposure light source is configured for irradiating the film layer on the substrate while the film layer are exposed with a mask; the photoresist removing exposure light source is used in any one of the above methods of removing the photoresist remaining on a substrate or any one of the methods of manufacturing a display substrate and configured for irradiating the photoresist when the photoresist remaining on a substrate needs to be removed.

The photoresist removing exposure light source refers to the light source with which the photoresist can be exposed, such as short wavelength light source. The exposure light source is not limited to these embodiments and also may include any other types of the exposure light source that can expose the photoresist. These exposure light sources should be within the scope of the invention. The exposure light source has been described above in details and will not be iterated.

In embodiments of the present invention, after the substrate is subjected to the patterning process, the photoresist left on the substrate is removed by exposing the photoresist and developing the exposed photoresist. In this way, the necessities for the stripping apparatus used in stripping process, the high power apparatus and the chemical gas both used in the ashing process can be eliminated, thereby reducing the equipment cost and production cost.

What is described above is related to the illustrative embodiments of the disclosure only and not limitative to the scope of the disclosure; the scopes of the disclosure are defined by the accompanying claims.

The present application claims priority from Chinese Application Serial Number 201310446586.X filed on Sep. 26, 2013, the disclosure of which is hereby incorporated by reference herein in its entirety.

1. A method of removing a photoresist remaining on a substrate after the substrate is subjected to a patterning process, comprising:
exposing the photoresist remaining on the substrate after the substrate is subjected to the patterning process; and
removing the exposed photoresist by a developing process.

2. The method according to claim 1, wherein the step of exposing the photoresist remaining on the substrate after the substrate is subjected to the patterning process comprises:
determining exposure energy for exposing the photoresist by a thicknesses of the photoresist that needs to be removed; and
exposing the photoresist remaining on the substrate after the substrate is subjected to the patterning process with the determined exposure energy.

3. The method according to claim 2, wherein the removing of the photoresist remaining on the substrate after the substrate is subjected to the patterning process is to entirely strip off the photoresist remaining on the substrate after the substrate is subjected to the patterning process, and the thicknesses of the photoresist that needs to be removed is a maximum thickness of the photoresist remaining on the substrate after the substrate is subjected to the patterning process.

4. The method according to claim 2, wherein the removing of the photoresist remaining on the substrate after the substrate is subjected to the patterning process is to ash the photoresist remaining on the substrate after the substrate is subjected to the patterning process, and the thicknesses of the photoresist that needs to be removed is a partial thickness of the photoresist remaining on the substrate after the substrate is subjected to the patterning process.

5. The method according to claim 1, wherein the step of exposing the photoresist remaining on the substrate after the substrate is subjected to the patterning process comprises:
determining exposure intensity for exposing the photoresist by a thicknesses of the photoresist that needs to be removed, and exposing the photoresist remaining on the substrate after the substrate is subjected to the patterning process with the determined exposure intensity; or
determining exposure duration for exposing the photoresist by a thicknesses of the photoresist that needs to be removed, and exposing the photoresist remaining on the substrate after the substrate is subjected to the patterning process with the determined exposure duration.

6. The method according to claim 1, wherein the step of exposing the photoresist remaining on the substrate after the substrate is subjected to the patterning process comprises:
exposing the photoresist remaining on the substrate after the substrate is subjected to the patterning process by using an exposure light source.

7. The method according to claim 6, wherein the exposure light source is a strip-like light source, wherein the strip-like light source moves in a uniform velocity along a direction parallel to the substrate and simultaneously irradiates the substrate, so that exposure degree of the photoresist on the substrate is uniform.

8. The method according to claim 6, wherein the exposure light source is a surface light source, wherein the surface light source irradiates the substrate in a vertical direction, so that exposure degree of the photoresist on the substrate is uniform.

9. The method according to claim 6, wherein the exposure light source comprises a white light source or an ultraviolet light source.

10. A method of manufacturing a display substrate, comprising steps of: forming a device pattern on a substrate by a patterning process using a photoresist, and removing the photoresist remaining on a substrate after the substrate is subjected to the patterning process, wherein the step of removing the photoresist remaining on the substrate after the substrate is subjected to the patterning process comprises the method according to claim 1.

11. The method according to claim 10, wherein the step of forming a device pattern on a substrate by a patterning process using a photoresist comprises:
forming a material film of the device on the substrate;
forming a photoresist film on the material film of the device;
performing an exposing process with a mask and an developing process on the photoresist film to remove a portion of the photoresist film and expose a portion of the material film of the device, other portions of the photoresist film are left on the substrate; and
etching the exposed portion of the material film to form the device pattern.

12. The method according to claim 10, wherein the display substrate is a thin film transistor array substrate.

13. The method according to claim 12, wherein the thin film transistor array substrate comprises a thin film transistor (TFT), a pixel electrode, a gate line and a data line.

14. The method according to claim 13, wherein the device pattern comprises a gate, an active layer, source and drain electrodes; the pixel electrode, the gate line, or the data line.

15. An exposure apparatus, comprising: an exposure light source which comprises a mask exposure light source and a photoresist removing exposure light source, wherein the mask exposure light source is configured for irradiating a film layer on a substrate while the film layer are exposed with a mask; the photoresist removing exposure light source is configured for irradiating the photoresist on the substrate after the substrate is subjected to the patterning process during the method of removing the photoresist remaining on a substrate after the substrate is subjected to a patterning process according to claim 1.

16. The method according to claim 2, wherein the step of exposing the photoresist remaining on the substrate after the substrate is subjected to the patterning process comprises:
determining exposure intensity for exposing the photoresist by a thicknesses of the photoresist that needs to be removed, and exposing the photoresist remaining on the substrate after the substrate is subjected to the patterning process with the determined exposure intensity; or
determining exposure duration for exposing the photoresist by a thicknesses of the photoresist that needs to be removed, and exposing the photoresist remaining on the substrate after the substrate is subjected to the patterning process with the determined exposure duration.

17. The method according to claim 11, wherein the display substrate is a thin film transistor array substrate.
